(19) United States
(12) Patent Application Publication
(10) Pub. No.: US 2019/0198482 A1
(43) Pub. Date: Jun. 27, 2019

(54) SEMICONDUCTOR DEVICE

(71) Applicants: Kabushiki Kaisha Toshiba, Minato-ku (JP); Toshiba Electronic Devices & Storage Corporation, Minato-ku (JP)

(72) Inventor: Akito SHIMIZU, Yokohama (JP)

(73) Assignees: Kabushiki Kaisha Toshiba, Minato-ku (JP); Toshiba Electronic Devices & Storage Corporation, Minato-ku (JP)

(21) Appl. No.: 15/920,638

(22) Filed: Mar. 14, 2018

(30) Foreign Application Priority Data
Dec. 27, 2017 (JP) 2017-251109

(51) Int. Cl. H01L 25/065; H01L 23/00

(52) U.S. Cl. CPC H01L 25/0657; H01L 23/562; H01L 2225/06582; H01L 2225/0651; H01L 2225/06555; H01L 2225/06524

(57) ABSTRACT

A semiconductor device includes a first supporting body, a first adhesive body, a first chip, a second adhesive body, a second chip, and a resin sealing member. The first adhesive body is provided on the first supporting body. The first chip includes an integrated circuit, and is provided on the first adhesive body. The second adhesive body is provided on the first chip. The second chip is provided on the second adhesive body. A coefficient of linear expansion of the second chip is not less than −75% and not more than +50% of that of the first chip. A thickness of the second chip is not less than 0.3 times and not more than 1.7 times of that of the first chip. The resin sealing member is provided around the first supporting body, the first and second adhesive bodies, and the first and second chip.

### CROSS-REFERENCE TO RELATED APPLICATIONS

This application is based upon and claims the benefit of priority from Japanese Patent Application No. 2017-251109, filed on Dec. 27, 2017; the entire contents of which are incorporated herein by reference.

### FIELD

Embodiments described herein relate generally to a semiconductor device.

### BACKGROUND

A package sealing a semiconductor device is configured from a wide variety of materials such as a mold resin of epoxy or the like and a metal or the like. For example, a coefficient of linear expansion of the mold resin is different from a coefficient of linear expansion of a chip provided with an integrated circuit. A stress generated on a surface of the chip changes variously depending on mold formation, mounting to a circuit board, and an operating environment of the semiconductor device. The change of the stress is one of factors fluctuating electrical characteristics of the integrated circuit. In the semiconductor device, it is desired to suppress the fluctuation of the electrical characteristics of the integrated circuit.

### BRIEF DESCRIPTION OF THE DRAWINGS

FIG. 1A is a schematic cross-sectional view illustrating a semiconductor device according to a first embodiment, FIG. 1B is a schematic cross-sectional view illustrating a semiconductor device according to a first variation of the first embodiment, FIG. 1C is a schematic cross sectional view illustrating a semiconductor device according to another example of the first variation of the first embodiment, and FIG. 1D is a schematic cross-sectional view illustrating a semiconductor device according to a second variation of the first embodiment;

FIG. 2A is a schematic cross-sectional view illustrating a semiconductor device according to a reference example, FIG. 2B is a schematic plan view of the semiconductor device according to the reference example, and FIG. 2C is a view illustrating the relationship between a position of a first chip in an X-axis direction and a normal stress generated in the first chip;

FIG. 3A is a schematic cross-sectional view illustrating the semiconductor device according to the first embodiment, FIG. 3B is a schematic plan view illustrating the semiconductor device according to the first embodiment, and FIG. 3C is a view illustrating the relationship between a position of the first chip in the X-axis direction and a normal stress generated in the first chip;

FIG. 4 is a view illustrating the relationship between a coefficient of linear expansion of a second chip and a normal stress generating in the first chip;

FIG. 5A is a view illustrating the relationship between a value of a ratio of a thickness of the second chip to a thickness of the first chip and the normal stress generated in the first chip, and FIG. 5B is a view illustrating the relationship between the position of the first chip in the X-axis direction and the normal stress generated in the first chip;

FIG. 6A and FIG. 6B are schematic perspective views illustrating the semiconductor device according to the first embodiment, respectively;

FIG. 7A is a view illustrating the relationship between a value of a ratio of an area of the second chip and an area of the first chip and the normal stress generated in the first chip, and FIG. 7B is a schematic plan view illustrating the semiconductor device according to the first embodiment;

FIG. 8A is a schematic plan view illustrating an aspect ratio of the second chip, FIG. 8B is a view illustrating the relationship between the aspect ratio of the second chip and the normal stress (distribution in the X-axis direction) generated in the first chip, and FIG. 8C is a view illustrating the relationship between the aspect ratio of the second chip and the normal stress (distribution in the Y-axis direction) generated in the first chip;

FIG. 9A is a schematic cross-sectional view illustrating a semiconductor device according to a second embodiment, FIG. 9B is a schematic cross-sectional view illustrating a semiconductor device according to a first variation of the second embodiment, FIG. 9C is a schematic cross-sectional view illustrating a semiconductor device according to another example of the first variation of the second embodiment, and FIG. 9D is a schematic cross-sectional view illustrating a semiconductor device according to a second variation of the second embodiment;

FIG. 10 is a schematic perspective view illustrating the semiconductor device according to the second embodiment;

FIG. 11A is a schematic cross-sectional view illustrating a semiconductor device according to a third embodiment, FIG. 11B is a schematic cross-sectional view illustrating a semiconductor device according to a first variation of the third embodiment, FIG. 11C is a schematic cross-sectional view illustrating a semiconductor device according to another example of the first variation of the third embodiment, and FIG. 11D is a schematic cross-sectional view illustrating a semiconductor device according to a second variation of the third embodiment: and

FIG. 12A is a schematic cross-sectional view illustrating a semiconductor device according to a fourth embodiment, FIG. 12B is a schematic cross-sectional view illustrating a semiconductor device according to a first variation of the fourth embodiment, FIG. 12C is a schematic cross-sectional view illustrating a semiconductor device according to another example of the first variation of the fourth embodiment, and FIG. 12D is a schematic cross-sectional view illustrating a semiconductor device according to a second variation of the fourth embodiment.

### DETAILED DESCRIPTION

According to one embodiment, a semiconductor device includes a first supporting body, a first adhesive body, a first chip, a second adhesive body, a second chip, and a resin sealing member. The first adhesive body is provided on the first supporting body. The first chip includes an integrated circuit, and is provided on the first adhesive body. The second adhesive body is provided on the first chip. The second chip is provided on the second adhesive body. A coefficient of linear expansion of the second chip is not less than −75% and not more than +50% of a coefficient of linear expansion of the first chip. A thickness of the second chip in a first direction from the first chip toward the second adhesive body is not less than 0.3 times and not more than 1.7 times of a thickness of the first chip in the first direction. The resin sealing member is provided around the first supporting body, the first adhesive body, the first chip, the second adhesive body and the second chip.

Various embodiments will be described hereinafter with reference to the accompanying drawings.

The drawings are schematic and conceptual; and the relationships between the thickness and width of portions, the proportions of sizes among portions, etc., are not necessarily the same as the actual values thereof. Further, the dimensions and proportions may be illustrated differently among drawings, even for identical portions.

In the specification and drawings, components similar to those described or illustrated in a drawing thereinabove are marked with like reference numerals, and a detailed description is omitted as appropriate.

### First Embodiment

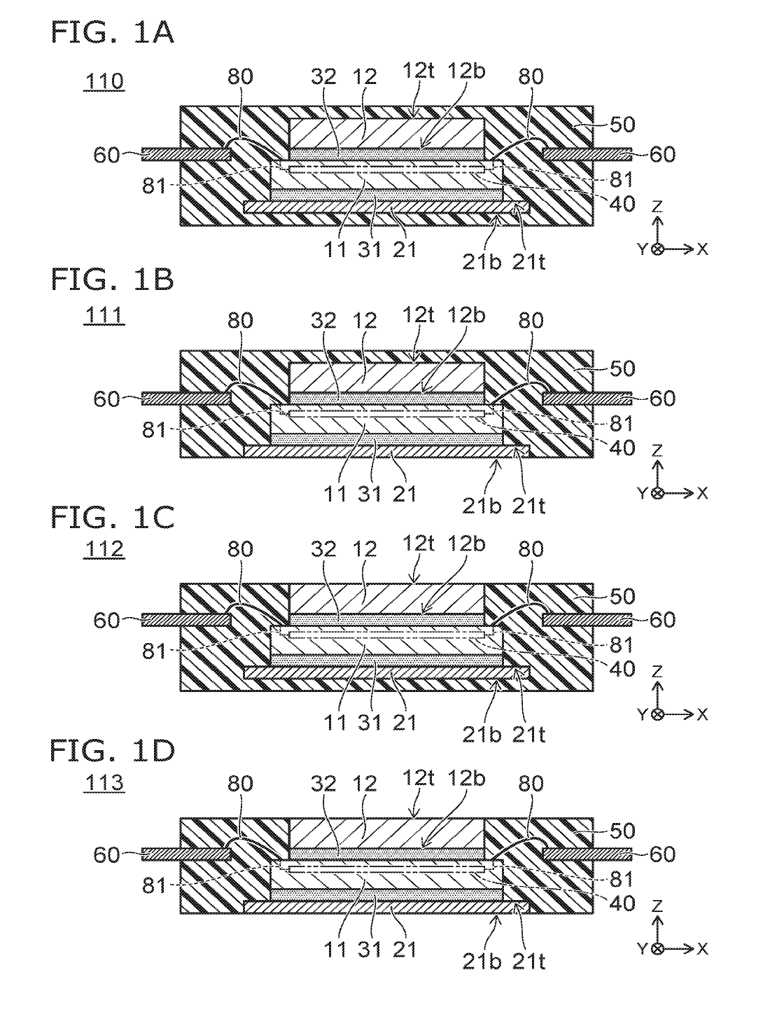

FIG. 1A is a schematic cross-sectional view illustrating a semiconductor device 110 according to a first embodiment. In the specification, a first direction is taken as a Z-axis direction. One direction crossing, for example, perpendicular to the Z-axis direction is taken as a second direction. The second direction is an X-axis direction. One direction crossing, for example, perpendicular to each of the Z-axis and X axis directions is taken as a third direction. The third direction is a Y-axis direction.

As shown in FIG. 1, the semiconductor device 110 according to the first embodiment includes a first supporting body 21, a first adhesive body 31, a first chip 11, a second adhesive body 32, a second chip 12, and a resin sealing member 50.

The first adhesive body 31 is provided on the first supporting body 21. The first chip 11 is provided on the first adhesive body 31. The first chip 11 includes an integrated circuit 40. The second adhesive body 32 is provided on the first chip 11. The second chip 12 is provided on the second adhesive body 32. The resin sealing member 50 is provided around the first supporting body 21, the first adhesive body 31, the first chip 11, the second adhesive body 32 and the second chip 12.

The supporting body 21 is, for example, made of a metal. The metal is, for example, an alloy including copper. The first, second adhesive bodies 31 and 32 are, for example, an adhesive resin paste. The resin paste includes, for example, an epoxy resin. Each of the first, second chips 11 and 12 is, for example, a semiconductor chip. The semiconductor chip is, for example, a silicon chip including silicon as a main component. However, the semiconductor chip is not limited to the silicon chip. The semiconductor chip may be a semiconductor chip adding an additive, for example, carbon to silicon, and may be a semiconductor chip including a compound semiconductor, for example, a group III-V compound semiconductor.

The first chip includes the integrated circuit 40, and is an electrically “active” semiconductor chip. On the other hand, the second chip 12 of the semiconductor device 110 does not include the integrated circuit 40. For example, even if the second chip 12 is a silicon chip, it is an electrically “inactive” semiconductor chip. The second chip 12 does not include the integrated circuit 40, and thus may not be a semiconductor chip.

The resin sealing member 50 is an insulative mold resin. The mold resin includes, for example, an epoxy resin. The resin sealing member 50 covers, for example, each of the first supporting body 21, the first adhesive body 31, the first chip 11, the second adhesive body 32, and the second chip 12. For example, the first supporting body 21 has a first surface 21b on an opposite side to a surface 21t opposing the first chip 11. The second chip 12 has a second surface 12t on an opposite side to a surface 12b opposing the first chip 11. The resin sealing member 50 covers each of the first surface 21b and the second surface 12t.

The semiconductor device 110 further includes a lead terminal 60 and a wiring member 80. The lead terminal 60 includes an inner lead portion and an outer lead portion. The wiring member 80 is electrically connected to the inner lead portion of the lead terminal 60 and the integrated circuit 40 of the first chip 11. The wiring member 80 is electrically connected to a bonding pad (not shown) provided in the first chip 11. The bonding pad is electrically connected to the integrated circuit 40 via a wiring 81 provided in the first chip 11.

The lead terminal 60 is, for example, made of a metal. The metal is, for example, an alloy including copper. The wiring member 80 is, for example, a bonding wire.

In the semiconductor device 110, the resin sealing member 50 further covers the inner lead portion of the lead terminal 60 and the wiring member 80. The outer lead portion of the lead terminal 60 appears outside the resin sealing member 50. The outer lead portion is possible to be electrically connected to a circuit board or the like.

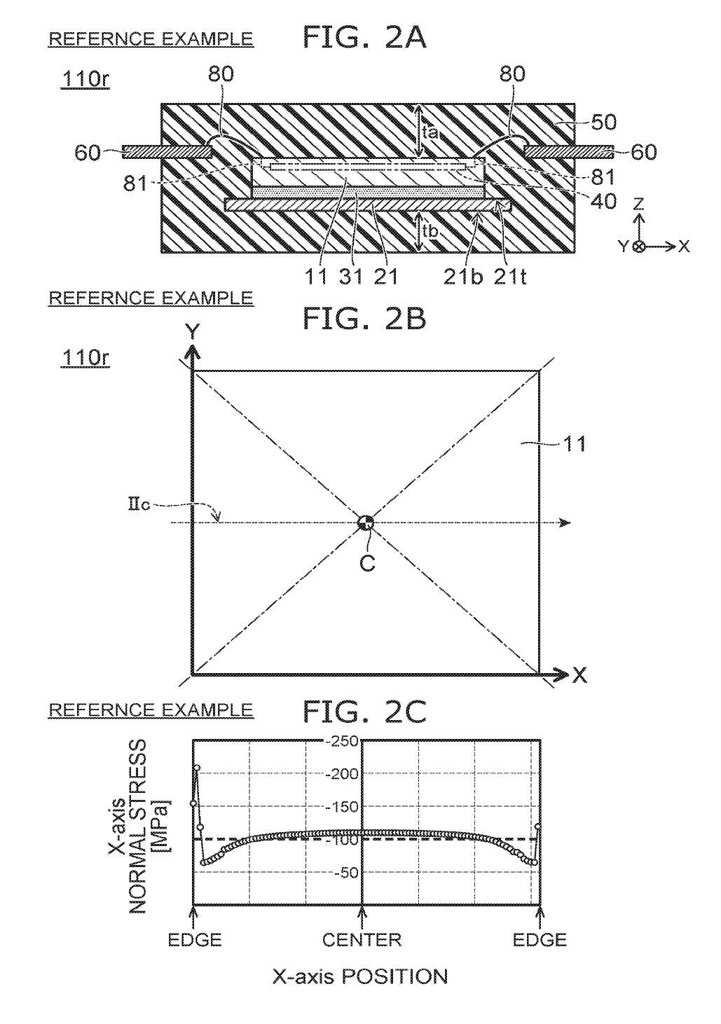

FIG. 2A is a schematic cross-sectional view illustrating a semiconductor device 110r according to a reference example. FIG. 2B is a schematic plan view of the semiconductor device 110r according to the reference example. FIG. 2C is a view illustrating the relationship between a position of a first chip in the X-axis direction (X-axis position) and a normal stress (X-axis normal stress) generated in the first chip. The relationship shown in FIG. 2C is, for example, the relationship along a broken line IIc shown in FIG. 2B. The broken line IIc is a straight line which passes through a center point C of the first chip 11, and is along the X-axis direction. The normal stress is a normal stress generated on an element forming surface provided with the integrated circuit 40 of the first chip 11. The relationship shown in FIG. 2C is, for example, obtained assuming the first chip 11 being a silicon chip and the resin sealing member 50 being an epoxy resin. The respective data described in the specification are obtained under the same condition as the data shown in FIG. 2C.

As shown in FIG. 2A and FIG. 2B, the semiconductor device 110r according to the reference example does not include the second chip 12. Therefore, as shown in FIG. 2C, a strong normal stress, for example, a normal stress of about −110 MPa is generated on the surface of the first chip 11.

The surface of the first chip 11 is, for example, an element forming surface of a chip provided with the integrated circuit 40. One of causes generating a normal stress is a difference of coefficients of linear expansion of the first chip 11 and the resin sealing member 50. Various heats are applied to the first chip 11 depending on mold formation, mounting to a circuit board, operation of the semiconductor device 110r, and an operating environment of the semiconductor device. The heat generates a normal stress onto the first chip 11. The normal stress generated on the first chip 11 causes the electrical characteristics of the integrated circuit 40 to fluctuate, for example, by a piezo effect.

The integrated circuit 40 included in the semiconductor device 110r according to the reference example is easily influenced by the piezo effect. Because of this, it is difficult to further improve the precision of the integrated circuit 40. For example, when the integrated circuit 40 includes an analogue circuit, it is more difficult to further improve the precision of the integrated circuit 40.

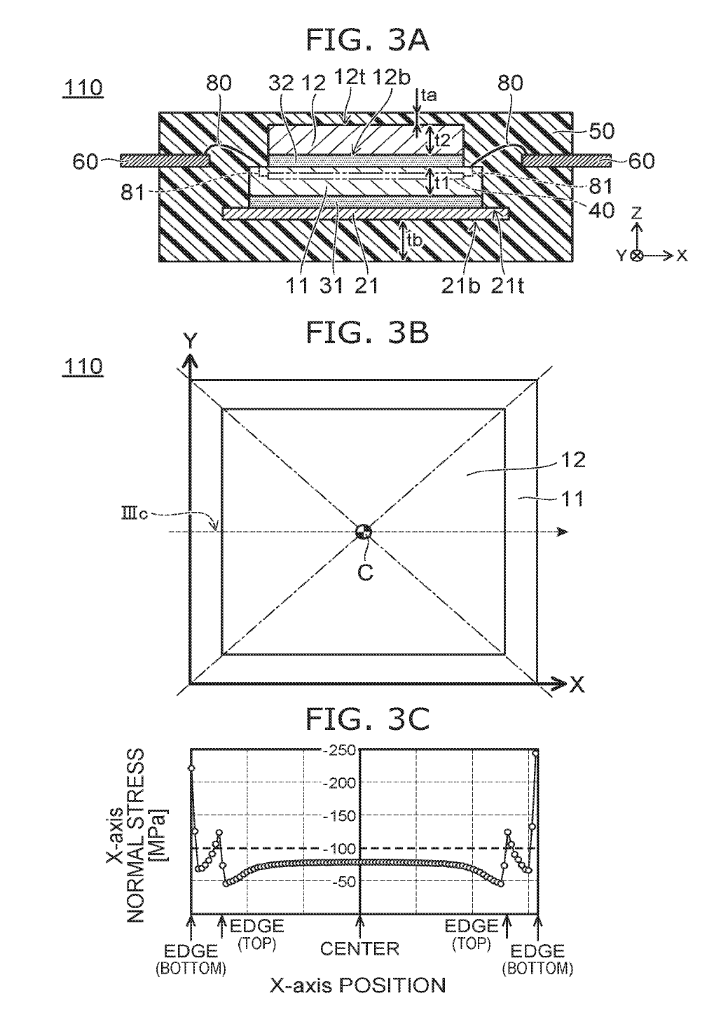

FIG. 3A is a schematic cross-sectional view illustrating the semiconductor device 110 according to the first embodiment. FIG. 3B is a schematic plan view illustrating the semiconductor device 110 according to the first embodiment. FIG. 3C is a view illustrating the relationship between a position of the first chip 11 in the X-axis direction and a normal stress generated in the first chip 11. The relationship shown in FIG. 3C is, for example, the relationship along a broken line IIIc shown in FIG. 3B. The broken line IIIc passes through the center point C of the first chip 11 and is a straight line along the X-axis direction.

The semiconductor device 110 according to the first embodiment shown in FIG. 3A further includes a second chip 12 in comparison with the semiconductor device 110r according to the reference example. Because of this, as shown in FIG. 3C, the normal stress generated on the surface of the first chip 11 can be reduced, for example, to about −80 to −90 MPa.

In this manner, according to the semiconductor device 110, the normal stress generated on the surface of the first chip 11 can be reduced and the electrical characteristics of the integrated circuit 40 provided in the first chip 11 can be suppressed from fluctuating.

(With Respect to Coefficients of Linear Expansion of the First, Second Chips 11 and 12)

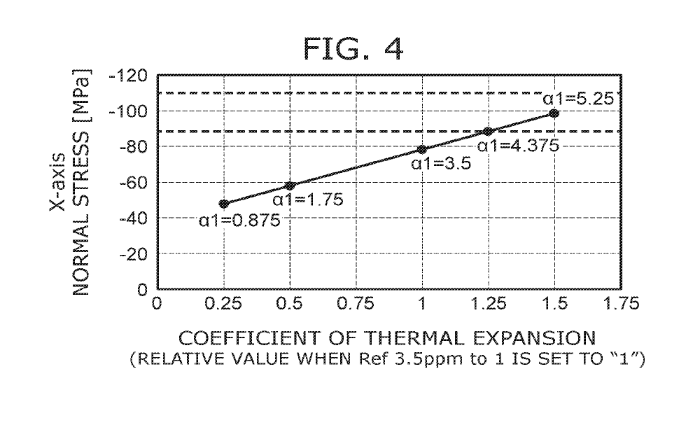

FIG. 4 is a view illustrating the relationship between coefficients of linear expansion (COEFFICIENT OF THERMAL EXPANSION) of the second chip 12 and the normal stress (X-axis NORMAL STRESS) generated in the first chip 11. FIG. 4 shows results of changing the coefficient of linear expansion al of the second chip 12 assuming the coefficient of linear expansion of the chip 11 of a reference value (REF) being “1(=3.5 ppm)”.

As shown in FIG. 4, it has been confirmed that the smaller the coefficient of linear expansion al of the second chip 12 than the coefficient of linear expansion of the first chip 11, the normal stress generated on the element forming surface of the chip 11 becomes small.

When the coefficient of linear expansion al of the second chip 12 is +50% (relative value: 1.5) to the coefficient of linear expansion of the second chip 11, the normal stress generated on the element forming surface of the first chip 11 is, for example, about −98 MPa. The normal stress is reduced to about 90% in comparison with about −110 MPa in the case of no second chip 12.

When the coefficient of linear expansion α1 is +25% (relative value: 1.25) to the coefficient of linear expansion of the second chip 11, the normal stress is, for example, about −88 MPa. The normal stress is reduced to about 80% in comparison with about −110 MPa in the case without the second chip 12.

In the following, when the coefficient of linear expansion α1 is ±0% (relative value: 1, the first chip 11 and the second chip 12 have the same material) to the coefficient of linear expansion of the second chip 11, the normal stress is, for example, about −78 MPa. When the coefficient of linear expansion α1 is −50% (relative value: 0.5) to the coefficient of linear expansion of the second chip 11, the normal stress is, for example, about −58 MPa. When the coefficient of linear expansion α1 is −75% (relative value: 0.25) to the coefficient of linear expansion of the second chip 11, the normal stress is, for example, about −48 MPa.

From the result shown in FIG. 4, it is favorable that the coefficient of linear expansion α1 of the second chip 12 is in a range of not less than −75% and not more than +50% of the coefficient of linear expansion of the second chip 11.

Furthermore, if the coefficient of linear expansion α1 of the second chip 12 is in a range of not less than −75% and not more than +25% of the coefficient of linear expansion of the second chip 11, the normal stress of the first chip 11 generated on the element forming surface can be reduced to about not more than 80% (about −88 MPa) in comparison with the case without the second chip 12.

(With Respect to a Ratio of Thicknesses of the First, Second Chips 11 and 12)

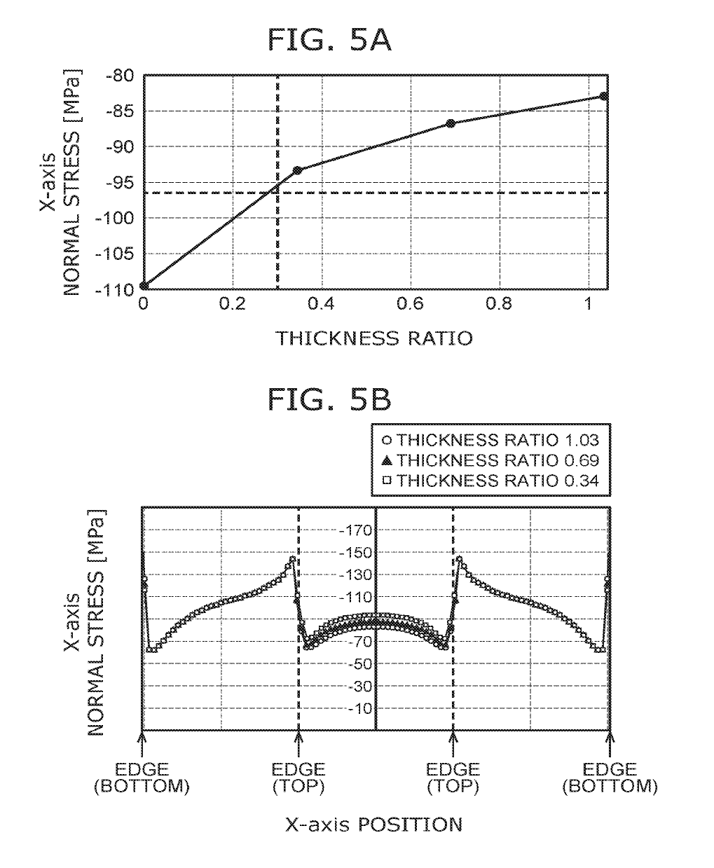

FIG. 5A is a view illustrating the relationship between a value of a ratio of a thickness of the second chip 12 to a thickness of the first chip 11 and the normal stress generated in the first chip 11. FIG. 5B is a view illustrating the relationship between a position of the first chip 11 in the X-axis direction and the normal stress generated in the first chip 11.

As shown in FIG. 5A, it has been confirmed that the nearer a thickness t2 (FIG. 3A) of the second chip 12 in the Z-axis direction is to a thickness t1 (FIG. 3A) of the first chip 11 in the Z-axis direction, the normal stress generated in the element forming surface of the first chip 11 becomes small.

In the case without the second chip 12, the normal stress generated on the element forming surface of the first chip 11 is about −110 MPa. When the thickness t2 is generally the same as the thickness t1 (≈11), the normal stress generated on the element forming surface of the first chip 11 is about −83 MPa. A difference of the normal stress is about −27 MPa. If the normal stress generated on the element forming surface of the first chip 11 can be reduced not more than about −96.5 MPa in a range of “t2≤t1”, it results in the normal stress being reduced to not more than about 50%. For example, if the thickness t2 of the second chip 12 is not less than about 0.3 times of the thickness of the first chip 11 in the first direction, the normal stress can be reduced to about not more than about −96.5 MPa. Therefore, the thickness t2 of the second chip 12 is, for example, favorable to be not less than 0.3 times of the thickness t1 of the first chip 11.

If the thickness t2 is thicker, there is a fear that the normal stress increases near an edge (EDGE BOTTOM˜EDGE TOP) of the element forming surface of the first chip 11. However, as shown in FIG. 5B, even if the thickness t2 becomes thick, it has not been confirmed that the normal stress increases near the edge of the element forming surface of the first chip 11. From this result, the thickness t2 is also possible to be not less than the thickness t1. The thickness t2 is possible to be up to 1.7 times (+70%) of the thickness t1. This is based on that the thickness t2 is ±70% (0.3 times ˜1.7 times) of the thickness t1. Therefore, the thickness t2 of the second chip 12 is, for example, favorable to be not less than 0.3 times and not more than 1.7 times of the thickness t1 of the first chip 11.

However, if the thickness t2 is thicker than the thickness t1, there is a fear that cost of the second chip 12 increases. Considering the cost increase, the thickness t2 is favorable to have an upper limit of approximately about 0.7 times (about 70%) of the thickness t1. For example, by setting the thickness t2 to be not less than 0.3 times and not more than 0.7 times of the thickness t1, while suppression of the cost and reduction of the normal stress generated on the element forming surface of the first chip 11 are compatible, the semiconductor device 110 can be produced.

A difference between the thickness t2 and the thickness t1 is preferred to be a finite value not more than ±100 μm. If the difference between the thickness t2 and the thickness t1 is large, it is anticipated that degree of coverage of the resin sealing member 50 is decreased. For example, by setting the difference between the thickness t2 and the thickness t1 to be a finite value not more than ±100 μm, the degree of coverage of the resin sealing member 50 can be suppressed from decreasing.

(With Respect to Shapes of XY-Planes of the First, Second Chips 11 and 12)

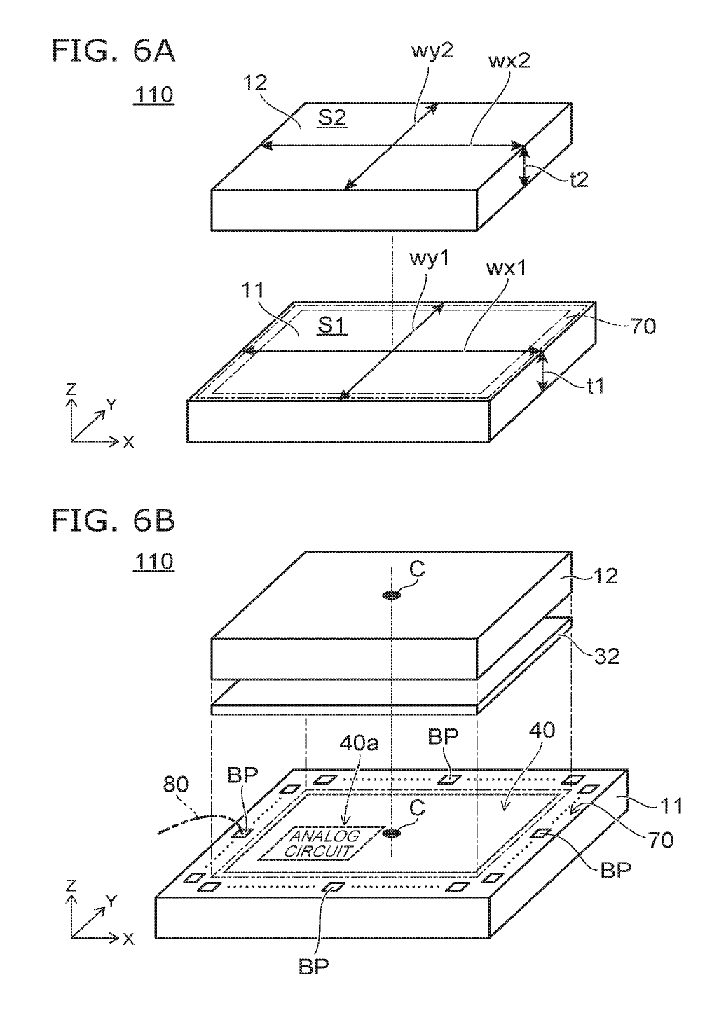

FIG. 6A and FIG. 6B are schematic perspective views illustrating the semiconductor device 110 according to the first embodiment, respectively.

As shown in FIG. 6A, in the semiconductor device 110, an area S2 (=wx2×wy2) of the XY-plane of the second chip 12 is smaller than an area S1 (=wx1×wy1) of the XY-plane of the first chip 11. If the area of the XY-plane of the second chip 12 is made smaller than the area of the XY-plane of the first chip 11, a non-overlapping region 70 not overlapping the second chip 12 can be set on the element forming surface of the first chip 11. The shape of the XY-plane of the non-overlapping region 70 is, for example, ring-shaped along each of four edges of the first chip 11. However, the XY-plane shape of the non-overlapping region 70 is not limited to be ring-shaped.

As shown in FIG. 6B, the non-overlapping region 70 can be provided with, for example, a plurality of bonding pads BP electrically connected to the integrated circuit 40. The bonding pads BP are provided along each of the four edges of the first chip 11. However, the bonding pads BP may not be provided along each of the four edges of the first chip 11. For example, the bonding pads BP may be either provided along one edge of the first chip 11 or provided along two edges facing each other. The wiring member 80 is electrically connected to the bonding pads BP.

In the case where the shape of the XY-plane of the non-overlapping region 70 is ring-shaped, the center point C in the XY-plane of the second chip 12 coincides with, for example, the center point C in the XY-plane of the first chip 11 in the Z-axis direction (FIG. 6B). Thereby, the shape of the XY-plane of the non-overlapping region 70 can be ring-shaped, and a distribution of the normal stress generated on the element forming surface of the first chip 11 can be, for example, uniformed along each of the X-axis direction and the Y-axis direction. Even if coincidence of the center points C in the Z-axis direction is not perfect, for example, “substantial coincidence” including allowable error in an assembly process may be allowed. It is also possible to shift intentionally the center points C in the Z-axis direction.

(With Respect to Overlapping of the First Chip 11 and the Second Chip 12)

As shown in FIG. 6B, the second chip 12 overlaps the integrated circuit 40 in the Z-axis direction. The integrated circuit 40 includes an analogue circuit 40a. The second chip 12 overlaps at least the analogue circuit 40a. The second chip 12 may overlap the whole of the integrated circuit 40 (FIG. 6B). A digital circuit is provided, for example, in the integrated circuit 40 other than the analogue circuit 40a.

The analogue circuit 40a is easily influenced by the normal stress in comparison with the digital circuit. Because of this, the fluctuation of the electrical characteristics of the integrated circuit 40 including the analogue circuit 40a can be controlled better by, for example, making the second chip 12 overlap the integrated circuit 40 including the analogue circuit 40a. One example of the analogue circuit 40a is a reference voltage generating circuit. In the case where, for example, the reference voltage generating circuit is used as the analogue circuit 40a, by comparing the reference voltage generated by the reference voltage generating circuit with a battery voltage (for example, external battery), the voltage of the external battery can be measured. In the embodiment, since the fluctuation of the reference voltage generated by the reference voltage generating circuit can be suppressed, for example, the accuracy of the measurement of the voltage of the external battery can be improved.

The analogue circuit 40a is disposed at a position shifted from the center point C of the first chip 11. However, in the semiconductor device 110, the normal stress at the center point C can be also reduced. Because of this, it is also possible to dispose the analogue circuit 40a to overlap the center point C. In this way, according to the semiconductor device 110, the advantage that freedom of layout of the analogue circuit 40a is improved can be obtained.

(With Respect to an Area Ratio of the First, Second Chips 11 and 12)

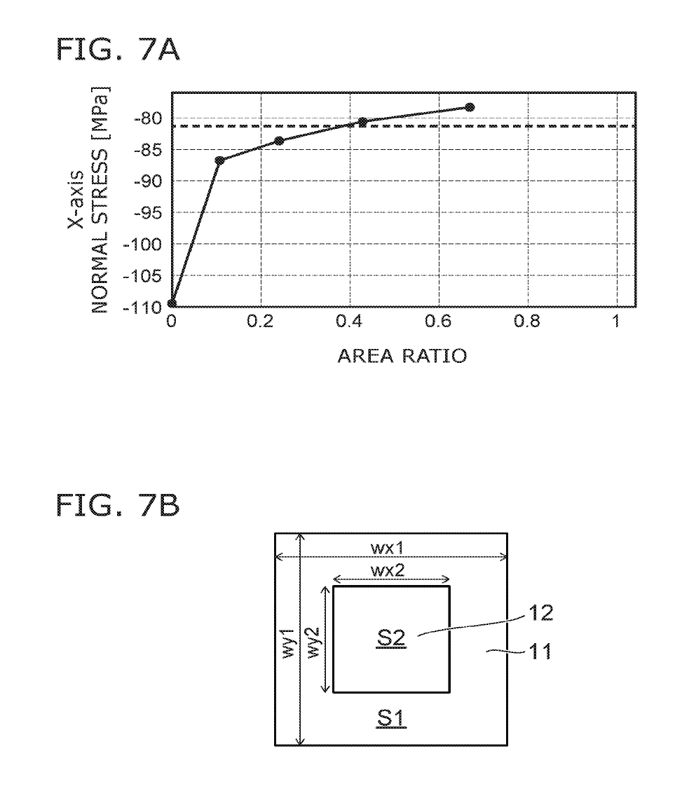

FIG. 7A is a view illustrating the relationship between a value of a ratio of an area of the second chip 12 to an area of the first chip 11 and the normal stress generated in the first chip 11. FIG. 7B is a schematic plan view illustrating the semiconductor device according to the first embodiment.

As shown in FIG. 7A, as a value S2/S1 of a ratio of the area S2 of the second chip 12 to the are S1 of the first chip 11 approaches “1”, the normal stress generated on the element forming surface of the first chip 11 becomes small. For example, when the value S2/S1 of the ratio of the area S2 to the area S1 is not less than 0.4, the normal stress can be reduced by not less than 80%. Therefore, the value S2/S1 of the ratio of the area S2 to the area S1 may be not less than 0.4. The area S2 may be larger than the area S1. In this case, an upper limit of the value S2/S1 of the ratio of the area S2 to the area S1 is 1.6. This is based on the area S2 being ±60% (0.4 times ˜1.6 times) of the area S1. Therefore, the value S2/S1 of the ratio of the area S2 to the area S1 is favorably not less than 0.4 and not more than 1.6.

However, if the area S2 is larger than the area S1, the cost of the second chip 12 increases. In the case where the cost is desired to be suppressed, it is favorable to set the value S2/S1 of the ratio of the area S2 to the area S1 to be not less than 0.4 and not more than 1.6.

As shown in FIG. 7B, in the case where the area S2 is different from the area S1, it is favorable that the shape of the XY-plane of the second chip 12 has a similar figure to the shape of the XY-plane of the first chip 11. For example, if the shape of the XY-plane of the second chip 12 has the similar figure to the shape of the XY-plane of the first chip 11, the distribution of the normal stress generated on the element forming surface of the first chip 11 is easy to be more uniform in both directions of the X-axis direction and the Y-axis direction.

(With Respect to an Aspect Ratio of the First, Second Chips 11 and 12)

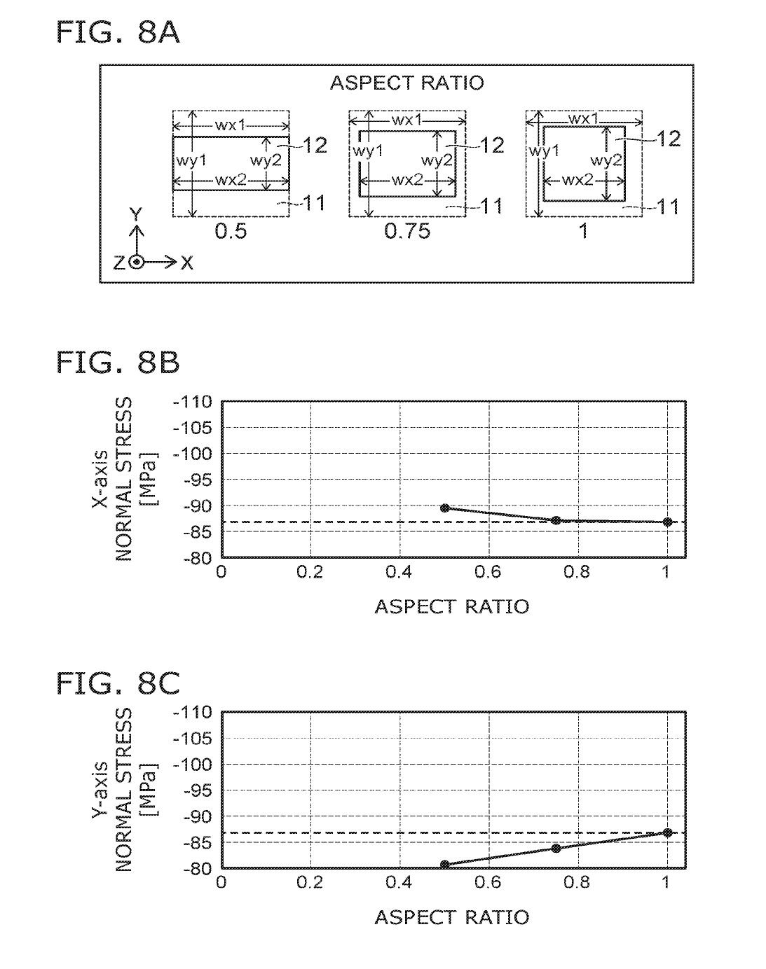

FIG. 8A is a schematic plan view illustrating an aspect ratio of the second chip 12. FIG. 8B is a view illustrating the relationship between the aspect ratio of the second chip 12 and the normal stress (distribution in the X-axis direction) generated in the first chip 11. FIG. 8C is a view illustrating the relationship between the aspect ratio of the second chip 12 and the normal stress (distribution if the Y-axis direction) generated in the first chip 11.

As shown in FIG. 8A, both shapes of the first, second chips 11 and 12 are rectangular. In this case, the shape of the XY-plane of the second chip 12 is not needed to have the similar figure to the shape of the XY-plane of the first chip 11. For example, the aspect ratio of the first chip 11 is set to be “1”. When the aspect ratio of the XY-plane of the second chip 12 is “1”, the shape of the XY-plane of the second chip 12 has the similar figure to the shape of the XY-plane of the first chip 11. On the contrary, the aspect ratio of the XY-planer of the second chip 12 can be also other than “1”, for example, not less than 0.5 and less than 1. In this case, the shape of the XY-plane of the second chip 12 has not the similar figure to the shape of the XY-plane of the first chip 11.

As shown in FIG. 8B, if the similar figure between the first chip 11 and the second chip 12 is broken, for example, the normal stress generated on the element forming surface of the first chip 11 increases in the X-axis direction, and the normal stress generated on the element forming surface of the first chip 11 decreases in the Y-axis direction. That is, the distribution of the normal stress generated on the element forming surface of the first chip is different in the X-axis direction and the Y-axis direction.

However, a difference between the normal stress in the X-axis direction and the normal stress in the Y-axis direction is slight, and the influence by the broken similar figure between the first chip 11 and the second chip 12 is small. Therefore, the first chip 11 and the second chip 12 do not always have the similar figure. For example, if the aspect ratio of the XY-plane of the second chip 12 is not less than 0.5, in comparison with the aspect ratio being 1, the normal stress in the X-axis direction and the normal stress in the Y-axis direction remain within the fluctuation range of approximately about ±5%, respectively. If the fluctuation range is intended to remain within approximately about ±5%, for example, a value wy2/wx2 of a ratio of a width wy2 of the second chip 12 in the Y-axis direction to a width wx2 of the second chip 12 in the X-axis direction may be set to not less than 0.5 and less than 1.

The result shown in FIG. 8B is obtained in the case where the aspect ratio of the XY-plane of the first chip 11 is fixed to “1”.

(With Respect to Thicknesses of the Resin Sealing Members on the First, Second Chips 11 and 12)

As shown in FIG. 3A, in the semiconductor device 110, for example, a thickness ta in the X-axis direction of the resin sealing member 50 on the second surface 12t is possible to be thinner than a thickness tb in the X-axis direction of the resin sealing member 50 on the first surface 21b. The thickness ta may be nearly equal to the thickness tb. The thickness ta may be thicker than the thickness tb.

In the semiconductor device 110, a value “ta/tb” of a ratio of the thickness ta to the thickness tb is set to be about 0.2˜0.3. Namely, the thickness ta is about ⅕ (about 20%) ˜⅓ (about 33%) of the thickness tb. Although the specific value changes depending on a type of the semiconductor device 110, one example includes the case where the thickness ta is about 110˜115 μm, the thickness tb is about 465˜470 μm.

As shown in FIG. 2A, in the semiconductor device 110r according to the reference example, a value “ta/tb” of a ratio of the thickness ta to the thickness tb is about 1. The reason why the value “ta/tb” of the ratio of the thickness ta to the thickness tb is set to not less than about 1 is to reduce the normal stress generated on the surface of the first chip 11. The normal stress generated on the surface of the first chip 11 can be reduced by setting the thickness ta and the thickness tb to be nearly equal.

On the contrary, in the semiconductor device 110, the second chip 12 is provided on the first chip 11. Because of this, even if the thickness ta is not set to be nearly equal to the thickness tb, the normal stress generated on the surface of the first chip 11 is possible to be reduced. In the semiconductor device 110, when the resin sealing member 50 is provided on the second chip 12, a lower limit of the value of the ratio of practical thickness ta to the thickness tb is, for example, about 0.2. Although described later, the resin sealing member 50 may not be on the second chip 12.

In the case where the resin sealing member 50 is on the second chip 12, the thickness ta is favorable to be not more than 120 μm practically. In the semiconductor device 110, the thickness ta is set within a range of about 112˜113 μm. For example, by setting the thickness ta to be, for example, not more than 120 μm, the thickness of the semiconductor device 110 in the Z-axis direction can be suppressed from increasing. Furthermore, a total value of the thickness ta and the thickness tb may be smaller than the thickness tb. In this case, the increase of the thickness of the semiconductor device 110 in the Z-axis direction due to the second chip 12 can be suppressed.

Moreover, for example, also in comparison with the thickness in the Z-axis direction of the semiconductor device 110r according to the reference example, the thickness in the Z-axis direction of the semiconductor device 110 is also possible to be thin. This is because that in the semiconductor device 110r according to the reference example, the value “ta/tb” of the ratio of the thickness ta to the thickness tb is about 1.

In the embodiment, the integrated circuit 40 includes the analogue circuit 40a. Although, in the embodiment, for example, the reference voltage generating circuit is illustrated as the analogue circuit 40a, the analogue circuit 40a may include an oscillation circuit. One example of the oscillation circuit is an RC oscillation circuit based on a resistance and a capacitor provided on silicon (silicon substrate of silicon layer). An oscillation frequency f of the RC oscillation circuit is proportional to an inverse of a product of a resistance value R and a capacitor value C (f∞1/(R·C)). In the embodiment, since the fluctuation of the resistance value R can be suppressed, for example, it is possible to improve an oscillation accuracy of the oscillation frequency f of the RC oscillation circuit.

### First Embodiment: First Variation

FIG. 1B is a schematic cross-sectional view illustrating a semiconductor device 111 according to a first variation of the first embodiment. FIG. 1C is a schematic cross-sectional view illustrating a semiconductor device 112 according to another example of the first variation of the first embodiment.

As shown in FIG. 1B and FIG. 1C, the first supporting body 21 has the first surface 21b on an opposite side to the surface 21t opposing the first chip 11. The second chip 12 has the second surface 12t on an opposite side to the surface 12b opposing the first chip 11. In the first variation, the resin sealing member 50 covers one of the first surface 21b and the second surface 12t.

In the semiconductor device 111 according to the first variation, the second surface 12t is covered with the resin sealing member 50, and the first surface 21b is exposed to the external from the resin sealing member 50 (FIG. 1B).

In the semiconductor device 112 according to another example of the first variation, the second surface 12t is exposed to the external from the resin sealing member 50, and the first surface 21b is covered with the resin sealing member 50 (FIG. 1C).

In this way, the resin sealing member 50 may cover one of the first surface 21b and the second surface 12t.

### First Embodiment: Second Variation

FIG. 1D is a schematic view illustrating a semiconductor device 113 according to a second variation of the first embodiment.

As shown in FIG. 1D, each of the first surface 21b and the second surface 12t may be exposed to the external from the resin sealing member 50.

### Second Embodiment

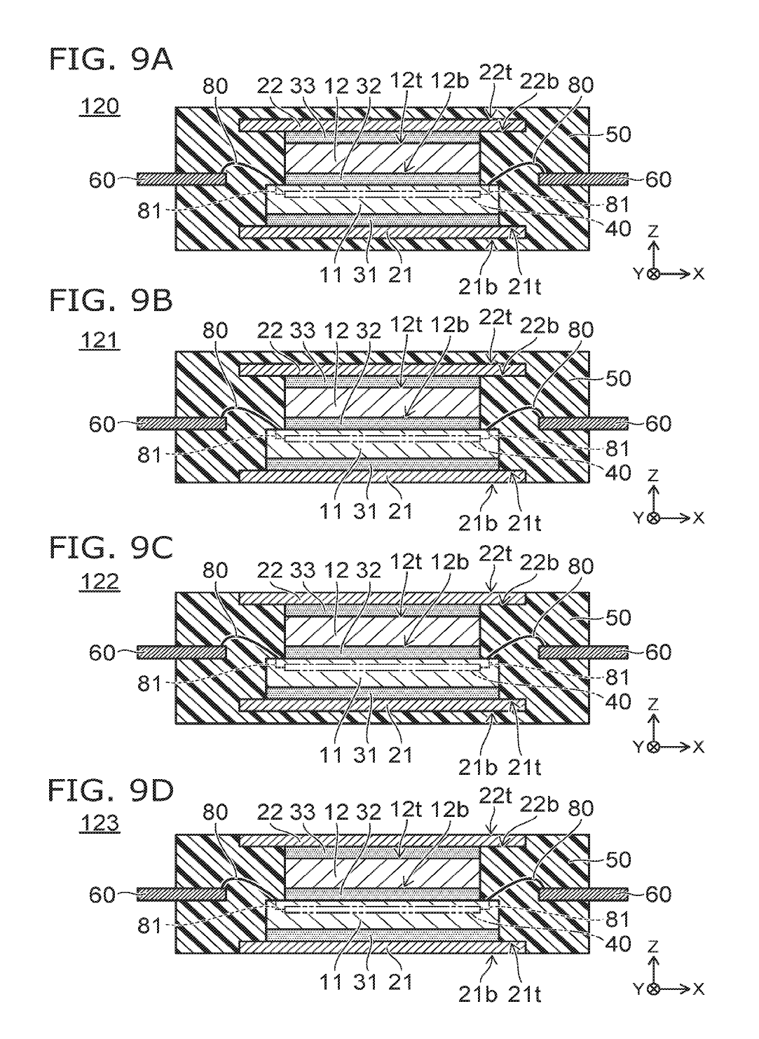

FIG. 9A is a schematic cross-sectional view illustrating a semiconductor device 120 according to a second embodiment.

As shown in FIG. 9A, the semiconductor device 120 according to the second embodiment further includes a second supporting body 22 in comparison with the semiconductor device 110.

The second supporting body 22 is provided on the second chip 12 via a third adhesive body 33. The resin sealing member 50 is further provided around the second supporting body 22. The first supporting body 21 has the first surface 21b on an opposite side to the surface 21t opposing the first chip 11. The second supporting body has a third surface 22t on an opposite side to a surface 22b opposing the second chip 12. The resin sealing member 50 covers each of the first surface 21b and the third surface 22t.

The second supporting body 22 is, for example, made of the same metal as that of the supporting body 21. The metal is, for example, an alloy including copper. The third adhesive body 33 is, for example, a resin paste having the same adhesive property as the first, second adhesive bodies. The resin paste includes, for example, an epoxy resin.

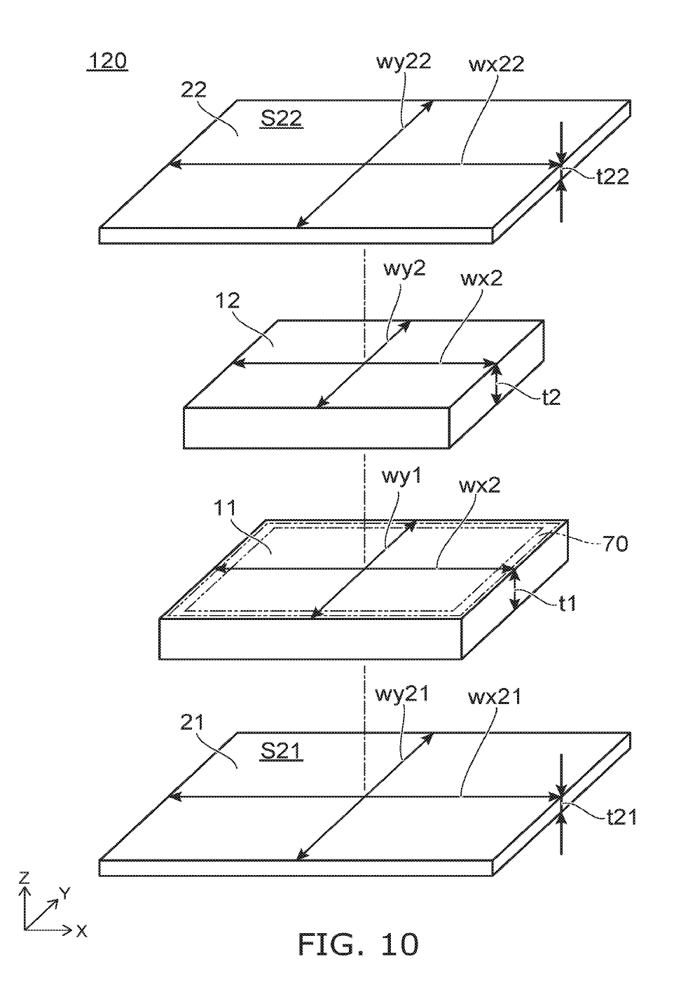

FIG. 10 is a schematic perspective view illustrating the semiconductor device according to the second embodiment.

As shown in FIG. 10, the shape of the XY-plane of the second supporting body 22 is, for example, substantially the same as the shape of the XY-plane of the first supporting body 21. That is, a width wx22 in the X-axis direction of the second supporting body 22, is for example, nearly equal to the width wx21 in the X-axis direction of the first supporting body 21. A width wy22 in the Y-axis direction of the second supporting body 22 is, for example, nearly equal to the width wy21 in the Y-axis direction of the first supporting body 21. A thickness t22 in the Z-axis direction of the second supporting body 22 is, for example, nearly equal to a thickness t21 in the Z-axis direction of the first supporting body 21.

Similar to the semiconductor device 120, it is also possible to further provide the second supporting body 22 on the second chip 12, for example, via the third adhesive body 33. In the semiconductor device 120, the second supporting body 22 is further included on the second chip 12. Because of this, in the interior of the semiconductor device 120, for example, a structure existing above and below the second adhesive body 32 as the boundary can be approached to more symmetric in comparison with the semiconductor device 110. Therefore, according to the semiconductor device 120, the normal stress generated on the element forming surface of the first chip 11 is possible to be further reduced.

Although the shape of the XY-plane of the second supporting body 22 is, for example, made substantially the same as the shape of the XY-plane of the first supporting body 21, it is also possible to be different from each other. For example, a value S22/S21 of a ratio of an area S22 of the XY-plane of the second supporting body 22 to an area S21 of the XY-plane of the first supporting body is not needed to be “1”. Each of a lower limit value and an upper limit value of the value S22/S21 of the ratio may be the same as the value S2/S1 of the ratio of the area S2 of the second chip 12 to the area S1 of the first chip 11. The value S22/S21 of the ratio of the area S22 to the area S21 may be set to not less than 0.4 and not more than 1.6.

FIG. 9B is a schematic cross-sectional view illustrating a semiconductor device 121 according to a first variation of the second embodiment. FIG. 9C is a schematic cross-sectional view illustrating a semiconductor device 122 according to another example of the first variation of the second embodiment.

### Second Embodiment: First Variation

As shown in FIG. 9B and FIG. 9C, the first supporting body 21 has the first surface 21b. The second supporting body 22 has the third surface 22t on an opposite side to the surface 22b opposing the second chip 12. In the first variation, the resin sealing member 50 covers one of the first surface 21b and the third surface 22t.

In the semiconductor device 121 according to the first variation, the third surface 22t is covered with the resin sealing member 50, and the first surface 21b is exposed to the external from the resin sealing member 50 (FIG. 9B).

In the semiconductor device 122 according to another example of the first variation, the third surface 22t is exposed to the external from the resin sealing member 50, and the first surface 21b is covered with the resin sealing member 50 (FIG. 9C).

In this way, the resin sealing member 50 may cover one of the first surface 21b and the third surface 22t.

### (Second Embodiment: Second Variation

FIG. 9D is a schematic cross-sectional view illustrating a semiconductor device 123 according to a second variation of the second embodiment.

As shown in FIG. 9D, each of the first surface 21b and the third surface 22t may be exposed to the external from the resin sealing member 50.

### Third Embodiment

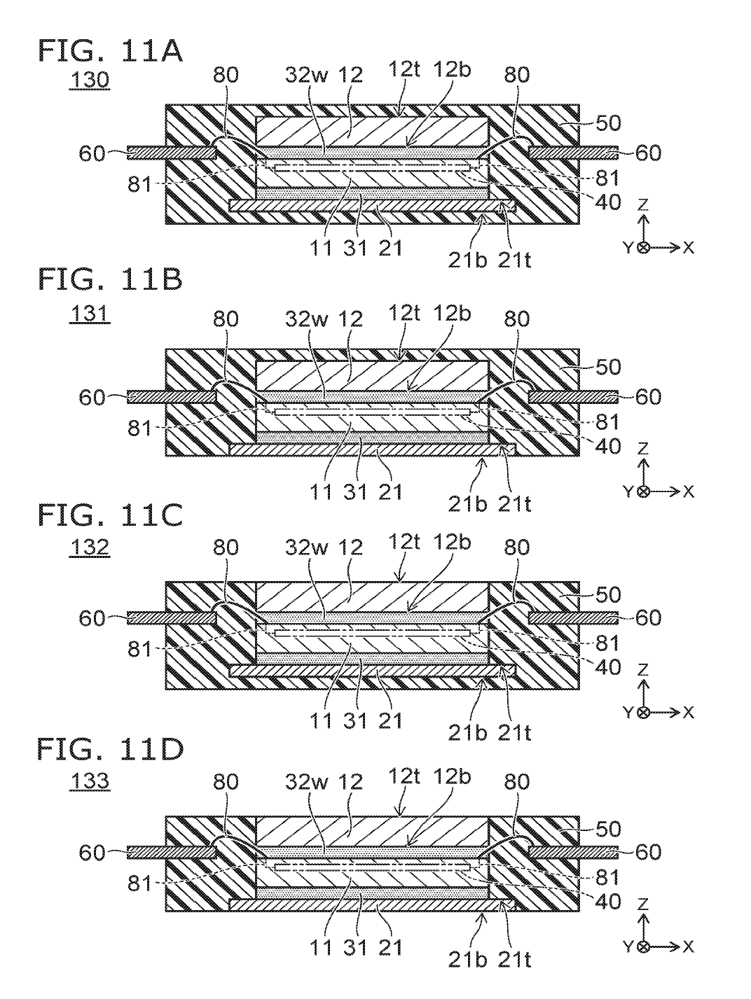

FIG. 11A is a schematic cross-sectional view illustrating a semiconductor device 130 according to a third embodiment.

As shown in FIG. 11A, the semiconductor device 130 according to the third embodiment has a length in the X-axis direction of the second chip 12 not less than a length in the X-axis direction of the first chip 11. FIG. 11A shows an example that the length in the X-axis direction of the second chip 12 is nearly equal to the length in the X-axis direction of the first chip 11. A value of the ratio of the area of the XY-plane of the second chip 12 to the area of the XY-plane of the first chip 11 is not less than 1. For example, in the semiconductor device 130, the area of the XY-plane of the second chip 12 is nearly equal to the area of the XY-plane of the first chip 11.

In the semiconductor device 130, for example, it is difficult to set the non-overlapping region 70 on the element forming surface of the first chip 11 similar to the semiconductor device 110. In such a case, the second adhesive body may be a second adhesive body 32w capable of allowing the wiring member 80 to pass through. In the semiconductor device 130, the wiring member 80 includes a portion passing through the second adhesive body 32w between the first chip 11 and the second chip 12.

The semiconductor device 130 can be formed by providing the second adhesive body 32w between the element forming surface of the first chip 11 and the surface 12b opposing the first chip 11 of the second chip 12 after bonding the wiring member 80 to the bonding pad of the first chip 11 (FIG. 6B).

In this way, according to the semiconductor device 130, the second adhesive body is set to the second adhesive body 32w capable of allowing the wiring member 80 to pass through. Thereby, even if there is no non-overlapping region 70 on the element forming surface of the first chip 11, the wiring member 80 can be electrically connected to the bonding pad of the first chip 11.

### Third Embodiment: First Variation

FIG. 11B is a schematic cross-sectional view illustrating a semiconductor device 131 according to a first variation of the third embodiment. FIG. 11C is a schematic cross-sectional view illustrating a semiconductor device 132 according to another example of the first variation of the third embodiment.

As shown in FIG. 11B, the semiconductor device 131 according to the first variation of the third embodiment is an example of combining the semiconductor device 111 (FIG. 1B) with the semiconductor device 130. As shown in FIG. 11C, the semiconductor device 132 according to the other example of the first variation of the third embodiment is an example of combining the semiconductor device 112 (FIG. 1C) with the semiconductor device 130.

In this way, the third embodiment is capable of combining with the first variation of the first embodiment.

FIG. 11D is a schematic cross-sectional view illustrating a semiconductor device 133 according to a second variation of the third embodiment.

### Third Embodiment: Second Variation

As shown in FIG. 11D, the semiconductor device 133 according to the second variation of the third embodiment is an example of combining the semiconductor device 113 (FIG. 1D) with the semiconductor device 130.

In this way, the third embodiment can be combined with the second variation of the first embodiment.

### Fourth Embodiment

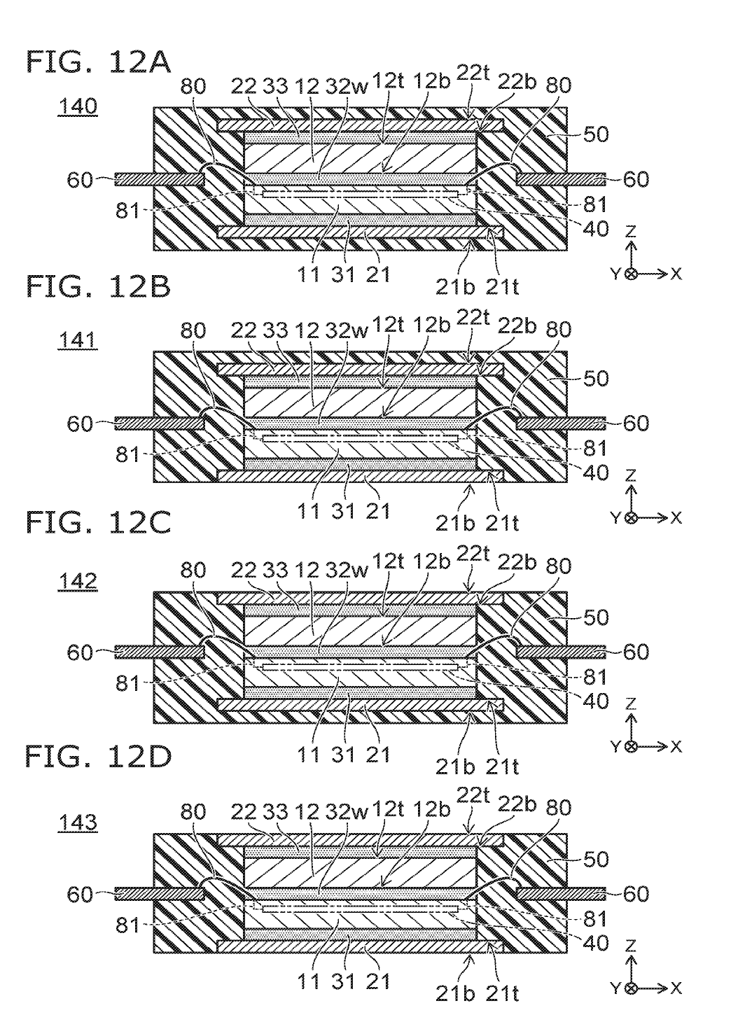

FIG. 12A is a schematic cross-sectional view illustrating a semiconductor device 140 according to a fourth embodiment.

As shown in FIG. 12A, the semiconductor device 140 according to the fourth embodiment is an example of combining the semiconductor device 120 (FIG. 9A) with the semiconductor device 130 (FIG. 11A).

Similar to the semiconductor device 140, it is possible to combine the second embodiment with the third embodiment.

### Fourth Embodiment: First Variation

FIG. 12B is a schematic cross-sectional view illustrating a semiconductor device 141 according to a first variation of the fourth embodiment. FIG. 12C is a schematic cross-sectional view illustrating a semiconductor device 142 according to another example of the first variation of the fourth embodiment.

As shown in FIG. 12B, the semiconductor device 141 according to the first variation of the fourth embodiment is an example of combining the semiconductor device 121 (FIG. 9B) with the semiconductor device 140. As shown in FIG. 12C, the semiconductor device 142 according to the other example of the first variation of the fourth embodiment is an example of combining the semiconductor device 122 (FIG. 9C) with the semiconductor device 140.

In this way, the fourth embodiment is possible to be combined with the first variation of the second embodiment.

### Fourth Embodiment: Second Variation

FIG. 12D is a schematic cross-sectional view illustrating a semiconductor device 143 according to a second variation of the fourth embodiment.

As shown in FIG. 12D, the semiconductor device 143 according to the second variation of the fourth embodiment is an example of combining the semiconductor device 133 (FIG. 9C) with the semiconductor device 140.

In this way, the fourth embodiment is possible to be combined with the second variation of the second embodiment.

As described above, according to the embodiments, a semiconductor device capable of suppressing the fluctuation of the electrical characteristics of the integrated circuit can be provided.

The embodiments of the invention have been described with reference to the specific examples and some variations. However, the embodiments of the invention are not limited to these specific examples and the variations. For example, semiconductor packages housing the first chip 11 and the second chip 12 or the like are possible to be applied to any of already existing semiconductor packages such as, for example, QFP (Quad Flat Package), QFN (Quad For Non-Lead Package) and BGA (Ball Gris Array) or the like.

Furthermore, one skilled in the art may similarly practice the invention by appropriately selecting specific configurations of components such as a first supporting body 21, a first adhesive body 31, a first chip 11, a second adhesive body 32, a second chip 12 and a resin sealing member 50, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices practicable by an appropriate design modification by one skilled in the art based on the semiconductor devices described above as embodiments of the invention also are within the scope of the invention to the extent that the spirit of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first supporting body;
a first adhesive body provided on the first supporting body;
a first chip including an integrated circuit, the first chip being provided on the first adhesive body;
a second adhesive body provided on the first chip;
a second chip provided on the second adhesive body, a coefficient of linear expansion of the second chip being not less than −75% and not more than +50% of a coefficient of linear expansion of the first chip, a thickness of the second chip in a first direction from the first chip toward the second adhesive body being not less than 0.3 times and not more than 1.7 times of a thickness of the first chip in the first direction; and
a resin sealing member provided around the first supporting body, the first adhesive body, the first chip, the second adhesive body and the second chip.

2. The device according to claim 1, wherein
the coefficient of linear expansion of the second chip is not less than −75% and not more than +25% of the coefficient of linear expansion of the first chip.

3. The device according to claim 1, wherein
a thickness of the second chip in the first direction is not less than 0.3 times and not more than 0.7 times of a thickness of the first chip in the first direction.

4. The device according to claim 1, wherein
a difference between the thickness of the second chip in the first direction and the thickness of the first chip in the first direction is not more than +100 μm.

5. The device according to claim 1, wherein
the first supporting body has a first surface on an opposite side to a surface opposing the first chip,
the second chip has a second surface on an opposite side to a surface opposing the first chip, and
the resin sealing member covers each of the first surface and the second surface.

6. The device according to claim 5, wherein
a thickness in the first direction of the resin sealing member on the second surface is thinner than a thickness in the first direction of the resin sealing member on the first surface.

7. The device according to claim 1, wherein
the first supporting body has a first surface on an opposite side to a surface opposing the first chip,
the second chip has a second surface on an opposite side to a surface opposing the first chip, and
the resin sealing member covers one of the first surface and the second surface.

8. The device according to claim 1, wherein
the first supporting body has a first surface on an opposite side to a surface opposing the first chip,
the second chip has a second surface on an opposite side to a surface opposing the first chip, and
each of the first surface and the second surface is exposed to an external.

9. The device according to claim 1, wherein
a value S2/S1 of a ratio of a second plane area S2 to a first plane area S1 is not less than 0.4 and not more than 1.6, the second plane of the second chip crossing the first direction, the first plane of the first chip crossing the first direction.

10. The device according to claim 1, wherein
a shape of a plane of the second chip crossing the first direction and a shape of a plane of the first chip crossing the first direction have a similar figure.

11. The device according to claim 1, wherein
a value wy2/wx2 of a ratio of a width wy2 in a second direction of the second chip to a width wx2 in a third direction of the second chip is not less than 0.5 and less than 1, the second direction crossing the first direction, the third direction crossing each of the first direction and the second direction.

12. The device according to claim 1, wherein
a center point of a plane of the second chip coincides with a center point of the first chip in the first direction, the plane of the second chip crossing the first direction, the plane of the first chip crossing the first direction.

13. The device according to claim 1, further comprising:
a lead terminal including an inner lead portion and an outer lead portion; and
a wiring member electrically connecting the inner lead portion of the lead terminal to the integrated circuit of the first chip,
the resin sealing member further covering the inner lead portion of the lead terminal.

14. The device according to claim 13, wherein
the wiring member includes a portion passing through the second adhesive body between the first chip and the second chip.

15. The device according to claim 1, further comprising:
a second supporting body provided on the second chip via a third adhesive body,
the resin sealing member being further provided around the second supporting body.

16. The device according to claim 15, wherein
the first supporting body has a first surface on an opposite side to a surface opposing the first chip,
the second supporting body has a third surface on an opposite side to a surface opposing the second chip, and
the resin sealing member covers each of the first surface and the third surface.

17. The device according to claim 15, wherein
the first supporting body has a first surface on an opposite side to a surface opposing the first chip,
the second supporting body has a third surface on an opposite side to a surface opposing the second chip, and
the resin sealing member covers one of the first surface and the third surface.

18. The device according to claim 15, wherein
the first supporting body has a first surface on an opposite side to a surface opposing the first chip,
the second supporting body has a third surface on an opposite side to a surface opposing the second chip, and
each of the first surface and the third surface is exposed to an external.

19. The device according to claim 1, wherein
the second chip overlaps the integrated circuit of the first chip in the first direction.

20. The device according to claim 1, wherein
the integrated circuit of the first chip includes an analogue circuit.
